(19) United States
(12) Patent Application Publication
(10) Pub. No.: US 2019/0207045 A1
(43) Pub. Date: Jul. 4, 2019

(54) SOLAR CELL MODULE INCLUDING A PLURALITY OF SOLAR CELLS

(71) Applicant: Panasonic Intellectual Property Management Co., Ltd., Osaka (JP)

(72) Inventor: Yuya NAKAMURA, Osaka (JP)

(21) Appl. No.: 16/299,927

(22) Filed: Mar. 12, 2019

Related U.S. Application Data
(63) Continuation of application No. PCT/JP2017/027754, filed on Jul. 31, 2017.

(30) Foreign Application Priority Data
Sep. 13, 2016 (JP) 2016-178913

(51) Int. Cl. H01L 31/0475; H01L 31/0224; H01L 31/02

(52) U.S. Cl. CPC H01L 31/0475; H01L 31/02021; H01L 31/022425

(57) ABSTRACT

A solar cell module includes: a plurality of solar cells; and a plurality of first-type wiring members electrically connecting adjacent solar cells. The solar cell includes: a photoelectric conversion layer; and a plurality of first-type and second-type finger electrodes. The plurality of first-type and second-type finger electrodes are arranged on a surface of the photoelectric conversion layer in a direction in which the plurality of first-type wiring members extend. A height of the plurality of first-type and second-type finger electrodes from the photoelectric conversion layer in a portion in which the plurality of first-type wiring members are provided is lower at an end of the photoelectric conversion layer than toward a center thereof.

### CROSS-REFERENCE TO RELATED APPLICATION

This application is a continuation of International Application PCT/JP2017/027754, filed on Jul. 31, 2017, which is based upon and claims the benefit of priority from the prior Japanese Patent Application No. 2016-178913, filed on Sep. 13, 2016, the entire contents of which are incorporated herein by reference.

### BACKGROUND

### 1. Field

The disclosure relates to a solar cell module and, more particularly, to a solar cell module including a plurality of solar cells.

### 2. Description

A solar cell module includes a plurality of solar cells electrically connected to each other between a surface protection member and a back surface protection member by means of a wiring tab. The solar cell includes a photoelectric conversion layer and a plurality of finger electrodes stacked on the photoelectric conversion layer. The photoelectric conversion layer, the finger electrodes, and the tab have different linear expansion coefficients. Therefore, a temperature change that occurs while the tab is being soldered to the solar cell could produce a stress in a region of intersection between the solar cell and the tab, which could result in disconnection in the finger electrodes. To inhibit reduction in an electrical output in the event of disconnection in the finger electrodes, the finger electrodes are caused to branch into a plurality of branches in the region of intersection, and the tab is spaced apart from the branch node of the branches (see, for example, JP2008-159895).

A wire film configured by connecting two transparent members by a plurality of wires may be used to simplify the manufacturing of a solar cell module. In the case a wire film is used in a solar cell module, the two transparent members are adhesively attached to adjacent solar cells respectively, and the wire is used as a wiring member. In the case the collecting electrode on the solar cell is made of a silver paste and the surface of the wire is coated with a solder of a low melting point, the adhesive force between the collecting electrode and the wire will be relatively low. If the adhesive force is low, the wire may be removed from the solar cell in a temperature cycle test.

### SUMMARY

The disclosure addresses the above-described issue, and a general purpose thereof is to provide a technology of improving the adhesive force between a solar cell and a wiring member.

A solar cell module according to an aspect of the disclosure includes: a plurality of solar cells; and a plurality of wiring members electrically connecting adjacent solar cells. Each of the plurality of solar cells includes: a photoelectric conversion layer; and a plurality of collecting electrodes arranged on a surface of the photoelectric conversion layer in a direction in which the plurality of wiring members extend. A height of the plurality of collecting electrodes from the photoelectric conversion layer in a portion in which the plurality of wiring members are provided is lower at an end of the photoelectric conversion layer than toward a center thereof.

### BRIEF DESCRIPTION OF THE DRAWINGS

The figures depict one or more implementations in accordance with the present teaching, by way of example only, not by way of limitations. In the figures, like reference numerals refer to the same or similar elements.

Embodiments will now be described, by way of example only, with reference to the accompanying drawings which are meant to be exemplary, not limiting, and wherein like elements are numbered alike in several Figures, in which:

FIG. 1 is a plan view showing a structure of a solar cell module according to Embodiment 1;

FIG. 2 is a cross sectional view of the solar cell module of FIG. 1;

FIG. 3 is a perspective view of a film used in the solar cell module of FIG. 1;

FIGS. 4A-4B are plan views showing the structure of the solar cell of FIG. 1;

FIGS. 5A-5F show partial features of the solar cell of FIG. 4; and

FIGS. 6A-6D show partial features of the solar cell according to Embodiment 2.

### DETAILED DESCRIPTION OF THE INVENTION

The invention will now be described by reference to the preferred embodiments. This does not intend to limit the scope of the present invention, but to exemplify the invention.

### Embodiment 1

A brief summary will be given before describing the disclosure in specific details. Embodiment 1 relates to a solar cell module in which a plurality of solar cells are arranged in a matrix. An encapsulant is provided between the first protection member and the second protection member in the solar cell module. The encapsulant encapsulates a plurality of solar cell. In this process, the two adjacent solar cells are connected by a wire film. As described above, a wire film is configured as two transparent members connected by a plurality of wires, and the respective transparent members are adhesively attached to adjacent solar cells. Since the wire plays the role of a wiring member, a string is formed by connecting a plurality of solar cells arranged in a direction of extension of the wire by means of a plurality of wire films. A wire film like this is used to simplify the manufacturing of a solar cell module. Meanwhile, in the case the collecting electrode on the solar cell is made of a silver paste and the surface of the wire is coated with a solder of a low melting point, the adhesive force between the collecting electrode and the wire will be relatively low. If the adhesive force is low, the wire may be removed from the solar cell when a temperature cycle test is performed to raise and lower the temperature repeatedly.

The embodiment improves the adhesive force between the solar cell and the wire even when a wire film is used, by causing the height of a portion (hereinafter, referred to as “region of intersection”) of a plurality of collecting electrodes in which a plurality of wires are provided to be lower at the ends of the solar cell than at the center thereof. The collecting electrodes are formed by screen printing. The quantity of silver paste used to form a lower portion is smaller than the quantity of silver paste used to form a higher portion. The smaller the quantity of silver paste, the smoother the surface of the collecting electrode, and, thus, the larger the area of contact between the collecting electrode and the wire. In other words, the area of contact between the collecting electrode and the wire is increased in a region of intersection at the ends of the solar cell than at the center thereof. It should be noted that an increase in the area of contact leads to an increase in the adhesive force. The terms “parallel” and “perpendicular” in the following description not only encompass completely parallel or perpendicular but also encompass off-parallel and off-perpendicular within the margin of error. The term “substantially” means identical within certain limits.

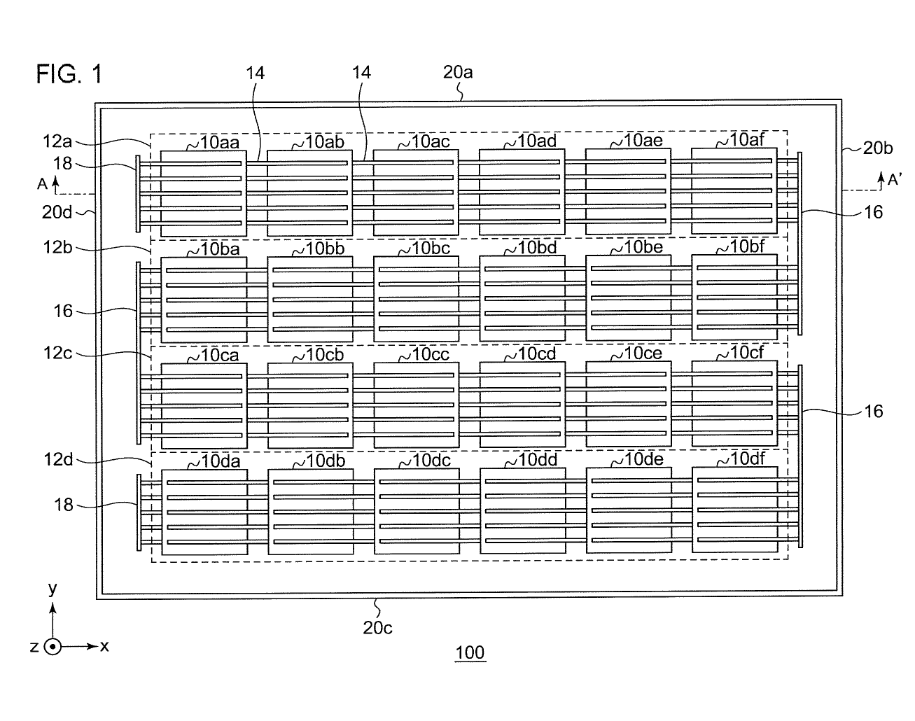

FIG. 1 is a plan view showing a structure of a solar cell module 100 according to Embodiment 1. As shown in FIG. 1, an orthogonal coordinate system including an x axis, y axis, and a z axis is defined. The x axis and y axis are orthogonal to each other in the plane of the solar cell module 100. The z axis is perpendicular to the x axis and y axis and extends in the direction of thickness of the solar cell module 100. The positive directions of the x axis, y axis, and z axis are defined in the directions of arrows in FIG. 1 and the negative directions are defined in the directions opposite to those of the arrows. Of the two principal surfaces forming the solar cell module 100 that are parallel to the x-y plane, the principal surface disposed on the positive direction side along the z axis is the light receiving surface, and the principal surface disposed on the negative direction side along the z axis is the back surface. Hereinafter, the positive direction side along the z axis will be referred to as “light receiving surface side” and the negative direction side along the z axis will be referred to as “back surface side”. Therefore, FIG. 1 can be said to be a plan view of the solar cell module 100 as viewed from the light receiving surface side.

The solar cell module 100 includes an 11th solar cell 10aa, . . . , a 46th solar cell 10df, which are generically referred to as solar cells 10, a first-type wiring member 14, a second-type wiring member 16, a third-type wiring member 18, a first frame 20a, a second frame 20b, a third frame 20c, and a fourth frame 20d, which are generically referred to as frames 20.

The first frame 20a extends in the x axis direction, and the second frame 20b extends in the negative direction along the y axis from the positive direction end of the first frame 20a along the x axis. Further, the third frame 20c extends in the negative direction along the x axis from the negative direction end of the second frame 20b along the y axis, and the fourth frame 20d connects the negative direction end of the third frame 20c along the x axis and the negative direction end of the first frame 20a along the x axis. The frames 20 bound the outer circumference of the solar cell module 100 and is made of a metal such as aluminum. The first frame 20a and the third frame 20c are longer than the second frame 20b and the fourth frame 20d, respectively, so that the solar cell module 100 has a rectangular shape longer in the x axis direction than in the y axis direction.

Each of the plurality of solar cells 10 absorbs incident light and generates photovoltaic power. In particular, the solar cell 10 generates an electromotive force from the light absorbed on the light receiving surface and also generates photovoltaic power from the light absorbed on the back surface. The solar cell 10 is formed of, for example, a semiconductor material such as crystalline silicon, gallium arsenide (GaAs), or indium phosphorus (InP). The structure of the solar cell 10 is not limited to any particular type. It is assumed that crystalline silicon and amorphous silicon are stacked by way of example. The solar cell 10 is formed in a rectangular shape on the x-y plane but may have other shapes. For example, the solar cell 10 may have an octagonal shape. A plurality of finger electrodes (not shown in FIG. 1) extending in the y axis direction in a mutually parallel manner are disposed on the light receiving surface and the back surface of each solar cell 10.

The plurality of solar cells 10 are arranged in a matrix on the x-y plane. In this case, six solar cells 10 are arranged in the x axis direction. The 6 solar cells 10 arranged and disposed in the x axis direction are connected in series by the first-type wiring member 14 so as to form one string 12. For example, a first string 12a is formed by connecting the 11th solar cell 10aa, the 12th solar cell 10ab, . . . , and the 16th solar cell 10af. The second string 12b through the fourth string 12d are similarly formed. As a result, the four strings 12 are arranged in parallel in the y axis direction. Thus, the number of solar cells 10 arranged in the x axis direction is larger than the number of solar cells 10 arranged in the y axis direction. When the x axis direction is referred to as the “first direction”, the y axis direction is referred to as the “second direction”. The number of solar cells 10 included in the string 12 is not limited to “6”, and the number of strings 12 is not limited to “4”.

In order to form the string 12, the first-type wiring members 14 connect the finger electrodes on the light receiving surface side of one of the solar cells 10 adjacent to each other in the x axis direction to the finger electrodes on the back surface side of the other. For example, the five first-type wiring members 14 for connecting the 11th solar cell 10aa and the 12th solar cell 10ab adjacent to each other electrically connect the finger electrodes on the back surface side of the 11th solar cell 10aa and the finger electrodes on the light receiving surface side of the 12th solar cell 10ab. The number of first-type wiring members 14 is not limited to “5”. The first-type wiring member 14 corresponds to the wire mentioned above. Connection between the first-type wiring member 14 and the solar cell 10 will be described below.

The second-type wiring member 16 extends in the y axis direction and electrically connect the two adjacent strings 12. For example, the 16th solar cell 10af located at the positive direction end of the first string 12a along the x axis and the 26th solar cell 10bf located at the positive direction end of the second string 12b along the x axis are electrically connected by the second-type wiring member 16. Further, the second string 12b and the third string 12c are electrically connected by the second-type wiring member 16 at the negative direction end along the x axis, and the third string 12c and the fourth string 12d are electrically connected by the second-type wiring member 16 at the positive direction end along the x axis. As a result, the plurality of strings 12 are connected in series by the second-type wiring member 16.

The second-type wiring member 16 is not connected to the 11th solar cell 10aa at the negative direction end of the first string 12a along the x axis. Instead the third-type wiring member 18 is connected. A lead wiring member (not shown) is connected to the third-type wiring member 18. The lead wiring member is a wiring member for retrieving the electric power generated in the plurality of solar cells 10 outside the solar cell module 100. The third-type wiring member 18 is also connected to the 41st solar cell 10da at the negative direction end of the fourth string 12d along the x axis.

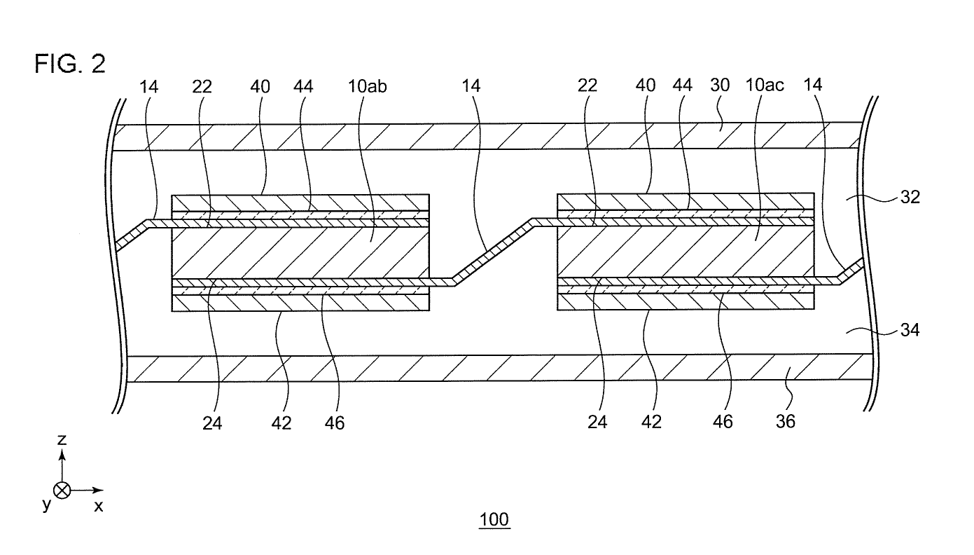

FIG. 2 is a cross sectional view of the solar cell module 100 along the x axis and is an A-A cross sectional view of FIG. 1. The solar cell module 100 includes a 12th solar cell 10ab, a 13th solar cell 10ac, the first-type wiring member 14, a first protection member 30, a first encapsulant 32, a second encapsulant 34, a second protection member 36, a first transparent member 40, a second transparent member 42, a first adhesive agent 44, and a second adhesive agent 46. The top of FIG. 2 corresponds to the light receiving surface, and the bottom corresponds to the back surface.

The first protection member 30 is disposed on the light receiving surface side of the solar cell module 100 and protects the surface of the solar cell module 100. Further, the solar cell module 100 is shaped in a rectangle bounded by the frame 20 on the x-y plane. The first protection member 30 is formed by using a translucent and water shielding glass, translucent plastic, etc. The first protection member 30 increases the mechanical strength of the solar cell module 100.

The first encapsulant 32 is stacked on the back surface side of the first protection member 30. The first encapsulant 32 is disposed between the first protection member 30 and the solar cell 10 and adhesively bonds the first protection member 30 and the solar cell 10. For example, a thermoplastic resin film of polyolefin, ethylene-vinyl acetate copolymer (EVA), polyvinyl butyral (PVB), polyimide, or the like may be used as the first encapsulant 32. A thermosetting resin may alternatively be used. The first encapsulant 32 is formed by a translucent sheet member having a surface of substantially the same dimension as the x-y plane in the first protection member 30.

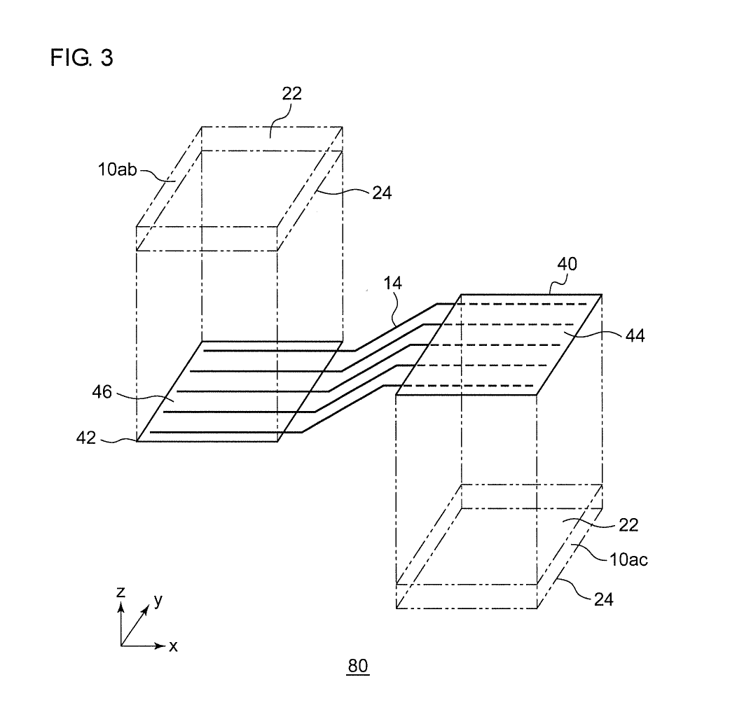

The 12th solar cell 10ab and the 13th solar cell 10ac are stacked on the back surface side of the first protection member 30. The solar cells 10 are provided such that the light receiving surface 22 faces the positive direction side along the z axis and the back surface 24 faces the negative direction side along the z axis. When the light receiving surface 22 is referred to as the “first surface”, the back surface 24 is referred to as the “second surface”. The first-type wiring member 14, the first adhesive agent 44, and the first transparent member 40 are provided on the light receiving surface 22 of the solar cell 10, and the first-type wiring member 14, the second adhesive agent 46, and the second transparent member 42 are provided on the back surface 24 of the solar cell 10. FIG. 3 will be used to describe the above arrangement in the solar cell 10.

FIG. 3 is a perspective view of a resin sheet 80 used in the solar cell module 100. The resin sheet 80 includes the first-type wiring member 14, the first transparent member 40, the second transparent member 42, the first adhesive agent 44, and the second adhesive agent 46. The resin sheet 80 corresponds to the wire film mentioned above.

The first transparent member 40 is provided on the light receiving surface 22 of one of the two adjacent solar cells 10 (for example, the 13th solar cell 10ac). The first transparent member 40 is comprised of a transparent resin film of, for example, polyethylene terephthalate (PET). The first transparent member 40 has a rectangular shape of a size substantially identical to that of the solar cell 10 on the x-y plane. The first adhesive agent 44 is provided on the surface of the first transparent member 40 toward the 13th solar cell 10ac, and a plurality of first-type wiring members 14 are provided on the first adhesive agent 44. The first adhesive agent 44 can adhesively bond the light receiving surface 22 of the 13th solar cell 10ac to the first transparent member 40. For example, EVA is used for the first adhesive agent 44.

The second transparent member 42 is provided on the side of the back surface 24 of the other of the two adjacent solar cells 10 (for example, the 12th solar cell 10ab). Like the first transparent member 40, the second transparent member 42 is comprised of a transparent resin film of, for example, PET. The second transparent member 42 has a rectangular shape of a size substantially identical to that of the solar cell 10 on the x-y plane. The second adhesive agent 46 is provided on the surface of the second transparent member 42 toward the 12th solar cell 10ab, and a plurality of first-type wiring members 14 are provided on the second adhesive agent 46. The second adhesive agent 46 can adhesively bond the back surface 24 of the 12th solar cell 10ab to the second transparent member 42. EVA is used for the second adhesive agent 46, too.

The resin sheet 80 is manufactured in advance, separate from the manufacturing of the solar cell module 100. When the solar cell module 100 is manufactured, the first adhesive agent 44 is adhesively bonded to the light receiving surface 22 of the 13th solar cell 10ac, and the second adhesive agent 46 is adhesively bonded to the back surface 24 of the 12th solar cell 10ab. By adhesive bonding as described above, the first-type wiring members 14 electrically connect the finger electrodes (not shown) on the light receiving surface 22 of the 13th solar cell 10ac to the finger electrodes (not shown) on the back surface 24 of the 12th solar cell 10ab. Reference is made back to FIG. 2.

By adhesively bonding the first transparent member 40 and the second transparent member 42 to other solar cells 10, the string 12 as shown in FIG. 1 is formed. The second encapsulant 34 is stacked on the back surface of the first encapsulant 32. The second encapsulant 34 encapsulates the plurality of solar cells 10, the first-type wiring members 14, the second-type wiring members 16, the third-type wiring members 18, the first transparent members 40, the second transparent members 42, etc., sandwiching the cells and the members between the first encapsulant 32 and the second encapsulant 34. The same member as used for the first encapsulant 32 may be used for the second encapsulant 34. Alternatively, the second encapsulant 34 may be integrated with the first encapsulant 32 by heating the members in a laminate cure process.

The second protection member 36 is stacked on the back surface side of the second encapsulant 34 so as to be opposite to the first protection member 30. The second protection member 36 protects the back surface side of the solar cell module 100 as a back sheet. A resin film of, for example, PET, polytetrafluoroethylene (PTFE), etc., a stack film having a structure in which an Al foil is sandwiched by resin films of polyolefin, or the like is used as the second protection member 36.

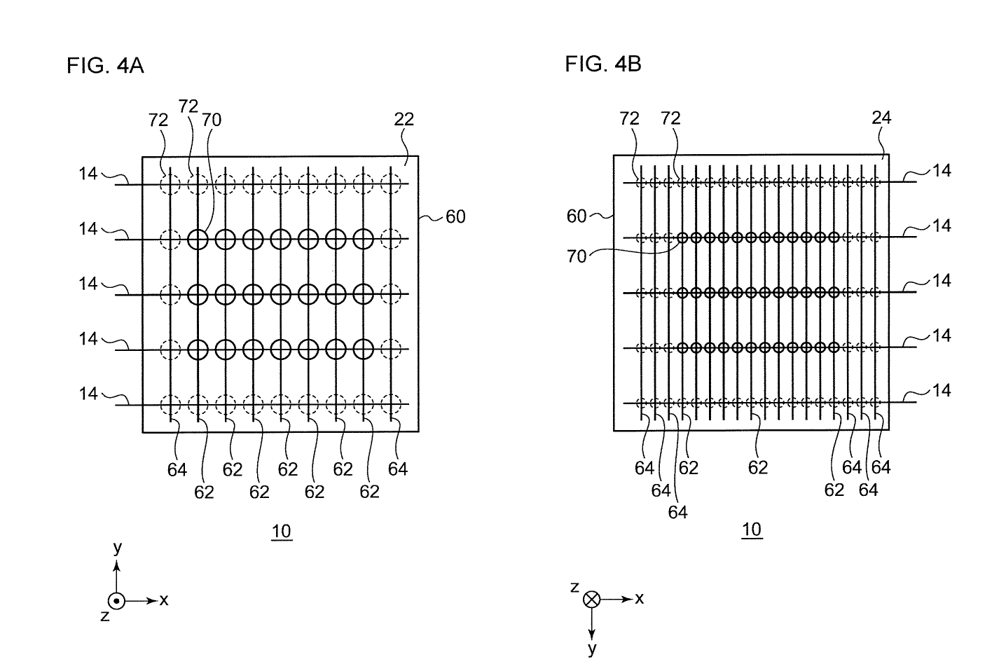

Connection between the finger electrode and the first-type wiring member 14 in the solar cell 10 will be described in further detail below. FIGS. 4A-4B are plan views showing the structure of the solar cell 10. FIG. 4A shows the light receiving surface 22 of the solar cell 10, and FIG. 4B shows the back surface 24 of the solar cell 10. For clarification of the description, illustration of the first transparent member 40, the second transparent member 42, the first adhesive agent 44, and the second adhesive agent 46 is omitted, and only the solar cell 10 and the first-type wiring member 14 are shown.

The photoelectric conversion layer 60 corresponds to the semiconductor material mentioned above and has a rectangular shape as mentioned above. Hereinafter, the surface of the photoelectric conversion layer 60 on the positive direction side along the z axis will also be referred to as the “light receiving surface 22”, and the surface of the photoelectric conversion layer 60 on the negative direction side along the z axis will also be referred to as the “back surface 24”. When the light receiving surface 22 is referred to as the “first surface”, the back surface 24 is referred to as the “second surface”. As shown in FIG. 4A, a first-type finger electrodes 62 and a second-type finger electrode 64 extending in the y axis direction are arranged in a plurality of columns on the light receiving surface 22 of the photoelectric conversion layer 60 in the x axis direction. The feature of the first-type finger electrode 62 and the second-type finger electrode 64 will be described later. Both are finger electrodes and correspond to the collecting electrode described above. The first-type finger electrode 62 and the second-type finger electrode 64 are made of silver paste (including epoxy resin and ester) in which a resin and silver particles are mixed. The first-type finger electrodes 62 are arranged in a plurality of columns toward the center in the x axis direction, and the second-type finger electrode 64 is provided at an end(s) in the x axis direction. In this example, the second-type finger electrode 64 is provided at the positive direction end and the negative direction end along the x axis.

A plurality of first-type wiring members 14 extending in the x axis direction are provided on the light receiving surface 22 of the photoelectric conversion layer 60 to intersect (e.g., to be orthogonal to) the first-type finger electrodes 62 and the second-type finger electrodes 64. The first-type wiring member 14 is formed by, for example, coating a copper core member having a substantially circular cross section with a solder of a low melting point. The metallic density of the first-type wiring member 14 is higher than the metallic density of the first-type finger electrodes 62 and the second-type finger electrodes 64. Therefore, the electric resistivity of the first-type wiring member 14 is smaller than the electric resistivity of the first-type finger electrodes 62 and the second-type finger electrodes 64.

Portions of the first-type finger electrodes 62 and the second-type finger electrodes 64 that intersect the plurality of first-type wiring members 14 respectively are referred to as “regions of intersection”. In the first-type finger electrode 62, a first region of intersection 70 is provided toward the center in the y axis direction, and a second region of intersection 72 is provided at the ends in the y axis direction. In this example, the first region of intersection 70 is provided in the three first-type wiring members 14 provided toward the center in the y axis direction, and the second region of intersection 72 is provided for the first-type wiring members 14 provided at the positive direction end and the negative direction end along the y axis. For the purpose of clear illustration, the neighborhood of the first region of intersection 70 is indicated by a solid circle, and the neighborhood of the second region of intersection 72 is indicated by a dotted circle. The feature of the first region of intersection 70 and the second region of intersection 72 will be described later. In the second-type finger electrode 64, on the other hand, only a plurality of second regions of intersection 72 are provided, and the first region of intersection 70 is not provided. In other words, the first-type finger electrode 62 and the second-type finger electrode 64 differ only in respect of the arrangement of the first region of intersection 70 and the second region of intersection 72 and are configured to be identical in the other respects.

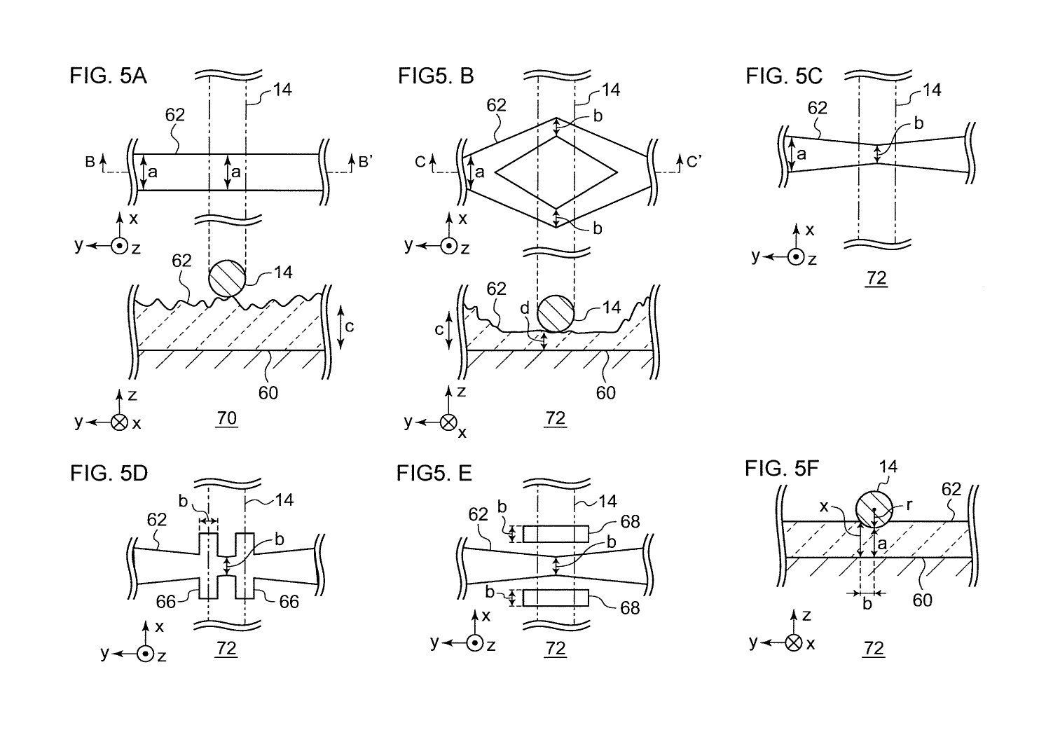

FIGS. 5A-5F show partial features of the solar cell 10. FIG. 5A shows a feature of the first-type finger electrode 62 and the first-type wiring member 14 in the first region of intersection 70. A plan view on the x-y plane is shown at the top, and a B-B′ cross sectional view of the plan view at the top is shown at the bottom. For clear illustration, the x axis and y axis are shown in different directions in the top figure and in FIG. 4A. As shown in the top figure in FIG. 5A, the width of the first-type finger electrode 62 in the x axis direction in a portion in which the first-type finger electrode 62 overlaps the first-type wiring member 14 and that of a portion in which they do not overlap are both “a”. The former portion corresponds to the first region of intersection 70, and the latter corresponds to a portion distanced from the first region of intersection 70.

As shown in the bottom figure in FIG. 5A, the surface of the first-type finger electrode 62 on the positive direction side along the z axis is formed with asperities in which a plurality of projections are randomly arranged in the y axis direction. The asperities are formed by using silver paste of a quantity necessary to make sure that the height from the photoelectric conversion layer 60 is about “c” when the first-type finger electrode 62 is formed by screen printing or the like. The first-type wiring member 14 is adhesively bonded to the surface of the first-type finger electrode 62 on the positive direction side along the z axis.

FIG. 5B shows a feature of the first-type finger electrode 62 and the first-type wiring member 14 in the second region of intersection 72. A plan view on the x-y plane is shown at the top, and a C-C′ cross sectional view of the plan view at the top is shown at the bottom. The same feature as illustrated is provided in the second-type finger electrode 64 as well as in the first-type finger electrode 62. As shown in the top figure in FIG. 5B, the first-type finger electrode 62 branches into a plurality of branches in a portion in which the first-type finger electrode 62 overlaps the first-type wiring member 14, i.e., in the second region of intersection 72. The figure shows “2” branches, but the number of branches is not limited to “2”. Further, the width of the first-type finger electrode 62 in the x axis direction in the second region of intersection 72 is “b” and that of a portion distanced from the second region of intersection 72 is “a”, “a” and “b” being different. It should be noted that b<a. In other words, the width of the first-type finger electrode 62 in the x axis direction in the second region of intersection 72 is caused to be smaller than that of the portion distanced from the second region of intersection 72.

As shown in the bottom figure in FIG. 5B, the surface of the first-type finger electrode 62 on the positive direction side along the z axis is formed, in the portion distanced from the second region of intersection 72, with asperities, in which a plurality of projections are randomly arranged in the y axis direction, as in the case of the bottom figure in FIG. 5A. Meanwhile, the surface of the first-type finger electrode 62 on the positive direction side along the z axis is smoother in the second region of intersection 72 as the scale of the asperities comprised of a plurality of projections is reduced. As described above, the first-type finger electrode 62 has a smaller width in this portion so that the quantity of silver paste necessary to form the first-type finger electrode 62 by screen printing or the like is smaller. As a result, the height from the photoelectric conversion layer 60 is about “d”, and the scale of the asperities is reduced. It should be noted that d<c. The first-type wiring member 14 is adhesively bonded to the surface of the first-type finger electrode 62 on the positive direction side along the z axis.

Comparing the bottom figure in FIG. 5A with the bottom figure in FIG. 5B, the height of the first-type finger electrode 62 from the photoelectric conversion layer 60 in the second region of intersection 72 is caused to be lower than the height of the first-type finger electrode 62 from the photoelectric conversion layer 60 in the first region of intersection 70. Mapping these features of the first region of intersection 70 and the second region of intersection 72 to FIG. 4A, the height of the first-type finger electrode 62 and the second-type finger electrode 64 from the photoelectric conversion layer 60 in portions in which a plurality of first-type wiring members 14 are provided is lower at the ends of the photoelectric conversion layer 60 than toward the center thereof. Further, the height of the first-type finger electrode 62 from the photoelectric conversion layer 60 in portions in which a plurality of first-type wiring members 14 are provided is caused to be lower at the ends in the y axis direction than toward the center thereof. Still further, the height of the second-type finger electrode 64 from the photoelectric conversion layer 60 in portions in which a plurality of first-type wiring members 14 are provided is caused to be lower the height of the first-type finger electrode 62 in portions toward the center in which first-type wiring members 14 are provided.

FIG. 5C shows a feature of the first-type finger electrode 62 and the first-type wiring member 14 in the second region of intersection 72. The figure shows a variation to FIG. 5B and parallels the top figure of FIG. 5B. The same feature as illustrated is provided in the second-type finger electrode 64 as well as in the first-type finger electrode 62. The first-type finger electrode 62 is formed such that the first-type finger electrode 62 does not branch but is tapered to a smaller width in the portion of overlapping with the first-type wiring member 14, i.e., in the second region of intersection 72. The width of the first-type finger electrode 62 in the x axis direction is “b” in the second region of intersection 72 and “a” in the portion distanced from the second region of intersection 72, “a” and “b” being different. It should be noted that b<a as before. Meanwhile, the cross section in the second region of intersection 72 shown in FIG. 5C is as shown in the bottom figure in FIG. 5B.

FIG. 5D shows a variation to FIG. 5C. Two projections 66 projecting the x axis direction from the portion in which the width is reduced in the second region of intersection 72 are formed. The width of the projection 66 provided in the first-type finger electrode 62 in the second region of intersection 72 in the y axis direction may be substantially equal to the width “b” of the first-type finger electrode 62 in the x axis direction.

FIG. 5E shows another variation to FIG. 5C. Two auxiliary electrodes 68 extending in the y axis direction are formed in the neighborhood of the portion in which the width is reduced in the second region of intersection 72. The auxiliary electrode 68 is made of the same material as the first-type finger electrode 62 but is formed as an island not contiguous with the first-type finger electrode 62. The width of the auxiliary electrode 68 in the x axis direction may be substantially equal to the width “b” of the first-type finger electrode 62 in the x axis direction.

FIG. 5F shows a feature of the first-type finger electrode 62 and the first-type wiring member 14 in the second region of intersection 72. The figure shows an ideal form of FIG. 5B and parallels the bottom figure of FIG. 5B. The same feature as illustrated is provided in the second-type finger electrode 64 as well as in the first-type finger electrode 62. Denoting the radius of the cross section of the first-type wiring member 14 “r” and the thickness of the first-type finger electrode 62 in the z axis direction “x” and defining “a” and “b” as shown in FIG. 5F, the following relationship holds.

x−a=r−√(r²−b²)

As shown in FIG. 43, the first-type finger electrodes 62, the second-type finger electrodes 64, and the first-type wiring members 14 are provided on the back surface 24 of the photoelectric conversion layer 60, as in the case of FIG. 4A. The number of the first-type wiring members 14 on the light receiving surface 22 is equal to that of the back surface 24, but the total number of the first-type finger electrodes 62 and the second-type finger electrodes 64 is larger on the back surface 24 than on the light receiving surface 22. In this example, “3” second-type finger electrodes 64 are provided, starting at the positive direction end along the x axis, and “3” second-type finger electrodes 64 are provided, starting at the negative direction end along the x axis. Therefore, the number of the second-type finger electrodes 64 is larger on the back surface 24 of the photoelectric conversion layer 60 than on the light receiving surface 22. The number of the second-type finger electrodes 64 on the back surface 24 of the photoelectric conversion layer 60 may be equal to the number of the second-type finger electrodes 64 on the light receiving surface of the photoelectric conversion layer 60. Meanwhile, the first-type finger electrodes 62 are sandwiched by the second-type finger electrodes 64 in the x axis direction.

The second region of intersection 72 is provided at the ends of the first-type finger electrode 62 along the y axis, and the first region of intersection 70 is provided between the second regions of intersection 72. Thus, the first-type finger electrode 62 on the back surface 24 is configured in a manner similar to that of the light receiving surface 22. However, the number of the second regions of intersection 72 in the first-type finger electrodes 62 provided on the back surface 24 of the photoelectric conversion layer 60 may be larger than the number of the second regions of intersection in the first-type finger electrodes 62 provided on the light receiving surface 22 of the photoelectric conversion layer 60. For example, “2” second regions of intersection 72 may be provided, starting at the positive direction end along the y axis, and “2” second regions of intersection 72 may be provided, starting at the negative direction end along the y axis.

A description will now be given of a method of manufacturing the solar cell module 100. First, the resin sheet 80 is prepared. A string 12 is produced by laying the first transparent member 40 of the resin sheet 80 on one of the two adjacent solar cells 10 and laying the second transparent member 42 of the resin sheet 80 on the other of the two adjacent solar cells 10. A stack is produced by laying the first protection member 30, the first encapsulant 32, the string 12, the second encapsulant 34, and the second protection member 36 in the stated order in the positive-to-negative direction along the z axis. This is followed by a laminate cure process performed for the stack. In this process, air is drawn from the stack, and the stack is heated and pressurized so as to be integrated. In vacuum lamination in the laminate cure process, the temperature is set to about 50-140°, as mentioned before. Further, a terminal box is attached to the second protection member 36 using an adhesive.

According to the embodiment, the height of the plurality of finger electrodes in portions in which first-type wiring members 14 are provided is lower at the ends of the photoelectric conversion layer 60 than toward the center thereof. Therefore, the surface of the finger electrodes at the ends is smoothed. Since the surface of the finger electrode is smoothed at the ends, the area of contact between the first-type wiring member 14 and the finger electrode is increased. Since the area of contact between the first-type wiring member 14 and the finger electrode is increased, the adhesive force between the first-type wiring member 14 and the finger electrode is improved. By causing the finger electrode to branch into a plurality of branches in the portion in which the height from the photoelectric conversion layer 60 is lower, an increase in the electric resistivity is inhibited.

By providing the first-type finger electrode 62 including the first region of intersection 70 and the second region of intersection 72 toward the center and providing the second-type finger electrode 64 including only the second region of intersection 72 at the ends, the configuration is simplified. By ensuring that the number of the second-type finger electrodes 64 on the back surface 24 of the photoelectric conversion layer 60 is larger than that of the light receiving surface 22, the adhesive force between the solar cell 10 and the first-type wiring members 14 is improved even when the total number of the first-type finger electrodes 62 and the second-type finger electrodes 64 is large. Further, by ensuring that the number of the second regions of intersection 72 in the first-type finger electrodes 62 is larger on the back surface 24 than on the light receiving surface 22, the adhesive force between the solar cell 10 and the first-type wiring member 14 is improved even when the total number of the first-type finger electrodes 62 and the second-type finger electrodes 64 is large.

One embodiment of the disclosure is summarized below. A solar cell module 100 according to one embodiment includes a plurality of solar cells 10, and a plurality of first-type wiring members 14 electrically connecting adjacent solar cells 10. Each of the plurality of solar cells 10 includes a photoelectric conversion layer 60, and a plurality of first-type and second-type finger electrodes 62, 64 arranged on a surface of the photoelectric conversion layer 60 in a direction in which the plurality of first-type wiring members 14 extend. The height of the plurality of first-type and second-type finger electrodes 62, 64 from the photoelectric conversion layer 60 in a portion in which the plurality of first-type wiring members 14 are provided is lower at an end of the photoelectric conversion layer 60 than toward a center thereof.

The plurality of first-type and second-type finger electrodes 62, 64 may branch into a plurality of branches in a portion in which the height from the photoelectric conversion layer 60 is lower.

The plurality of first-type and second-type finger electrodes 62, 64 may include a first-type finger electrode 62 provided toward a center in a direction in which the plurality of first-type wiring members 14 extend and a second-type finger electrode 64 provided at an end in a direction in which the plurality of first-type wiring members 14 extend. A height of the first-type finger electrode 62 from the photoelectric conversion layer 60 in the portion in which the plurality of first-type wiring members 14 are provided is lower at an end in a direction in which the first-type finger electrode 62 extends than toward a center thereof, and a height of the second-type finger electrode 64 from the photoelectric conversion layer 60 in the portion in which the plurality of first-type wiring members 14 are provided is lower than the height of the first-type finger electrode 62 in portions toward the center in which the first-type wiring members 14 are provided.

The plurality of first-type and second-type finger electrodes 62, 64 are provided on both surfaces of the photoelectric conversion layer 60, and the number of the second-type finger electrodes 64 is larger on the back surface 24 of the photoelectric conversion layer 60 than on the light receiving surface 22 thereof.

The plurality of first-type and second-type finger electrodes 62, 64 are provided on both surfaces of the photoelectric conversion layer 60, and the number of portions of the first-type finger electrodes 62 provided on the back surface 24 of the photoelectric conversion layer 60 in which the height from the photoelectric conversion layer 60 is caused to be lower may be larger than the number of portions of the first-type finger electrodes 62 provided on the light receiving surface 22 of the photoelectric conversion layer 60 in which the height from the photoelectric conversion layer 60 is caused to be lower.

### Embodiment 2

A description will now be given of Embodiment 2. Like Embodiment 1, Embodiment 2 relates to a solar cell module that includes a string formed by adhesively attaching a resin film on solar cells. In Embodiment 1, the shape of the first-type wiring member remains unchanged irrespective of the first region of intersection and the second region of intersection. In Embodiment 2, on the other hand, the shape of the first-type wiring member varies depending on the first region of intersection or the second region of intersection is relevant. The solar cell module 100 according to Embodiment 2 is of a type similar to that of FIGS. 1, and 2, the resin sheet 80 is of a type similar to that of FIG. 3, and the solar cell 10 is of a type similar to that of FIGS. 4A-4B. The following description concerns a difference from the foregoing embodiments.

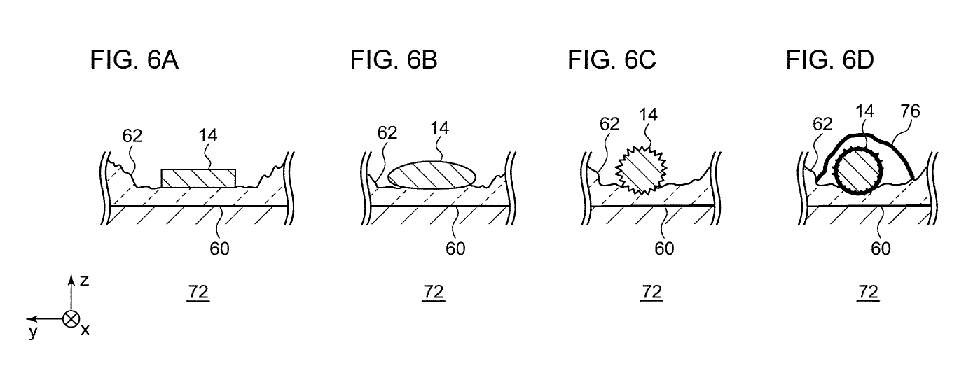

FIGS. 6A-6D show partial features of the solar cell 10 according to Embodiment 2. These figures parallel the bottom figure of FIG. 5B. Referring to FIGS. 6A-6D, the first-type finger electrode 62 is configured in a manner similar to that of FIG. 5B. The first-type wiring member 14 of FIG. 6A has a rectangular shape longer in the y axis direction than in the z axis direction. By forming the first-type wiring member 14 in a rectangular shape, the area of contact with the first-type finger electrode 62 will be larger than in the case where it is formed in a circular shape as in FIG. 5B.

The first-type wiring member 14 of FIG. 6B has an elliptical shape longer in the y axis direction than in the z axis direction. By forming the first-type wiring member 14 in an elliptical shape longer in the y axis direction than in the z axis direction, the area of contact with the first-type finger electrode 62 will be larger than in the case where it is formed in a circular shape. In other words, the area of the plurality of first-type wiring members 14 facing the photoelectric conversion layer 60 will be larger in the second region of intersection 72 of the photoelectric conversion layer 60 than in the first region of intersection 70. The first-type wiring member of FIG. 6C is provided with a plurality of projections on its surface. By providing a plurality of projections, the first-type wiring member 4 itself is fixed as if by being stuck in the first-type finger electrode 62 so that the adhesive force is increased. The first-type wiring member of FIG. 6D is provided with a protective resin 76 that covers the region of superimposition on the photoelectric conversion layer 60 and the region in the neighborhood. Since the first-type wiring member 14 and the photoelectric conversion layer 60 are fixed by the protective resin 76 as well, the adhesive force is increased. In this process, it is preferred to include a white material in the protective resin 76.

According to the embodiment, the area of the portion of the first-type wiring member 14 facing the portion of the photoelectric conversion layer 60 in which the finger electrode is provided is wider at the end of the photoelectric conversion layer 60 than toward the center. Therefore, the area of contact is increased at the end. Further, since the area of contact is increased at the end, the adhesive force between the first-type wiring member 14 and the finger electrode is increased.

One embodiment of the present invention is summarized below. The area of the plurality of first-type wiring member 14 facing the portion of the photoelectric conversion layer 60 in which the plurality of first-type and second-type finger electrodes 62, 64 are provided is wider at the end of the photoelectric conversion layer 60 than toward the center thereof.

Described above is an explanation based on an exemplary embodiment. The embodiment is intended to be illustrative only and it will be understood by those skilled in the art that various modifications to constituting elements and processes could be developed and that such modifications are also within the scope of the present invention.

Embodiment 1 and Embodiment 2 may be combined. According to this variation, the benefit from the combination is obtained.

In Embodiments 1 and 2, the resin sheet 80 is used. Alternatively, however, the resin sheet 80 may not be used, and the adjacent solar cells 10 may be connected by the first-type wiring member 14. In this case, the first-type wiring member 14 may not be a wire. According to this variation, the flexibility in the configuration can be improved.

In Embodiments 1 and 2, the second region of intersection 72 is provided near the end of the solar cell 10 and is not provided toward the center. However, the second region of intersection 72 may not necessarily be provided near the end of the solar cell 10 and may be provided in a location where the strength of bond between the solar cell 10 and the first-type wiring member is relatively low. By not providing the second region of intersection 72 in which the strength of bond between the solar cell 10 and the first-type wiring member 14 is relatively high, it is intended that the strength of bond between the solar cells 10 and the first-type wiring members 14 in the string 12 as a whole is maintained at a high level.

In Embodiment 2, the first regions of intersection 70 and the second regions of intersection 72 are provided in the first-type finger electrodes 62 and the second-type finger electrodes 64. Alternatively, however, only the first regions of intersection 70 may be provided. According to this variation, the configuration of the finger electrodes is unified.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What is claimed is:

1. A solar cell module comprising:
a plurality of solar cells; and
a plurality of wiring members electrically connecting adjacent solar cells, wherein
each of the plurality of solar cells includes:
a photoelectric conversion layer; and
a plurality of collecting electrodes arranged on a surface of the photoelectric conversion layer in a direction in which the plurality of wiring members extend, wherein
a height of the plurality of collecting electrodes from the photoelectric conversion layer in a portion in which the plurality of wiring members are provided is lower at an end of the photoelectric conversion layer than toward a center thereof.

2. The solar cell module according to claim 1, wherein
the plurality of collecting electrodes branch into a plurality of branches in a portion in which the height from the photoelectric conversion layer is lower.

3. The solar cell module according to claim 1, wherein
the plurality of collecting electrodes include a first-type collecting electrode provided toward a center in a direction in which the plurality of wiring members extend and a second-type collecting electrode provided at an end in a direction in which the plurality of wiring members extend,
a height of the first-type collecting electrode from the photoelectric conversion layer in the portion in which the plurality of wiring members are provided is lower at an end in a direction in which the first-type collecting electrode extends than toward a center thereof, and
a height of the second-type collecting electrode from the photoelectric conversion layer in the portion in which the plurality of wiring members are provided is lower than the height of the first-type collecting electrode in portions toward the center in which the wiring members are provided.

4. The solar cell module according to claim 2, wherein
the plurality of collecting electrodes include a first-type collecting electrode provided toward a center in a direction in which the plurality of wiring members extend and a second-type collecting electrode provided at an end in a direction in which the plurality of wiring members extend,
a height of the first-type collecting electrode from the photoelectric conversion layer in the portion in which the plurality of wiring members are provided is lower at an end in a direction in which the first-type collecting electrode extends than toward a center thereof, and
a height of the second-type collecting electrode from the photoelectric conversion layer in the portion in which the plurality of wiring members are provided is lower than the height of the first-type collecting electrode in portions toward the center in which the wiring members are provided.

5. The solar cell module according to claim 3, wherein
the plurality of collecting electrodes are provided on both surfaces of the photoelectric conversion layer, and
the number of the second-type collecting electrodes is larger on a second surface of the photoelectric conversion layer than on a first surface thereof.

6. The solar cell module according to claim 4, wherein
the plurality of collecting electrodes are provided on both surfaces of the photoelectric conversion layer, and
the number of the second-type collecting electrodes is larger on a second surface of the photoelectric conversion layer than on a first surface thereof.

7. The solar cell module according to claim 3, wherein
the plurality of collecting electrodes are provided on both surfaces of the photoelectric conversion layer, and
the number of portions of the first-type collecting electrodes provided on the second surface of the photoelectric conversion layer in which the height from the photoelectric conversion layer is caused to be lower is larger than the number of portions of the first-type collecting electrodes provided on the first surface of the photoelectric conversion layer in which the height from the photoelectric conversion layer is caused to be lower.

8. The solar cell module according to claim 4, wherein
the plurality of collecting electrodes are provided on both surfaces of the photoelectric conversion layer, and
the number of portions of the first-type collecting electrodes provided on the second surface of the photoelectric conversion layer in which the height from the photoelectric conversion layer is caused to be lower is larger than the number of portions of the first-type collecting electrodes provided on the first surface of the photoelectric conversion layer in which the height from the photoelectric conversion layer is caused to be lower.

9. The solar cell module according to claim 1, wherein
an area of the plurality of wiring members facing the portion of the photoelectric conversion layer in which the plurality of collecting electrodes are provided is wider at the end of the photoelectric conversion layer than toward the center thereof.

10. The solar cell module according to claim 2, wherein
an area of the plurality of wiring members facing the portion of the photoelectric conversion layer in which the plurality of collecting electrodes are provided is wider at the end of the photoelectric conversion layer than toward the center thereof.

11. The solar cell module according to claim 3, wherein
an area of the plurality of wiring members facing the portion of the photoelectric conversion layer in which the plurality of collecting electrodes are provided is wider at the end of the photoelectric conversion layer than toward the center thereof.

12. The solar cell module according to claim 4, wherein
an area of the plurality of wiring members facing the portion of the photoelectric conversion layer in which the plurality of collecting electrodes are provided is wider at the end of the photoelectric conversion layer than toward the center thereof.

13. The solar cell module according to claim 5, wherein
an area of the plurality of wiring members facing the portion of the photoelectric conversion layer in which the plurality of collecting electrodes are provided is wider at the end of the photoelectric conversion layer than toward the center thereof.

14. The solar cell module according to claim 6, wherein
an area of the plurality of wiring members facing the portion of the photoelectric conversion layer in which the plurality of collecting electrodes are provided is wider at the end of the photoelectric conversion layer than toward the center thereof.

15. The solar cell module according to claim 7, wherein
an area of the plurality of wiring members facing the portion of the photoelectric conversion layer in which the plurality of collecting electrodes are provided is wider at the end of the photoelectric conversion layer than toward the center thereof.

16. The solar cell module according to claim 8, wherein
an area of the plurality of wiring members facing the portion of the photoelectric conversion layer in which the plurality of collecting electrodes are provided is wider at the end of the photoelectric conversion layer than toward the center thereof.
